(19) United States
(12) Patent Application Publication
(10) Pub. No.: US 2008/0076246 A1
(43) Pub. Date: Mar. 27, 2008

(54) Through contact layer opening silicide and barrier layer formation

(76) Inventors: Brennan L. Peterson, Portland, OR (US); Vinay B. Chikarmane, Portland, OR (US); Kevin J. Fischer, Hillsboro, OR (US)

Correspondence Address: INTEL CORPORATION;c/o INTELLEVATE, LLC, P.O. BOX 52050, MINNEAPOLIS, MN, 55402, US

(21) Appl. No.: 11/527,367

(22) Filed: Sep. 25, 2006

(51) Int. Cl. H01L 21/44; H01L 21/8234; H01L 21/336; H01L 21/4763

(52) U.S. Cl. 438/655; 438/664; 438/592; 438/197; 438/299

(57) ABSTRACT

Embodiments of the invention include apparatuses and methods relating to through contact-opening silicide and barrier layer formation. In one embodiment, a silicide region is formed in a silicon substrate by deposition of a siliciding material in a contact opening and a subsequent anneal.

### TECHNICAL FIELD

Embodiments of the invention relate to microelectronics processing technology. In particular, embodiments of the invention relate to through contact layer opening silicide and barrier layer formation.

### BACKGROUND

In semiconductor processing technology, transistors are often formed on a silicon wafer and interconnected with other electrical components to form integrated circuits (ICs), which perform a wide variety of useful functions. In some applications, each transistor includes a source and a drain in a silicon substrate, a channel between the source and the drain, and a gate structure including a gate dielectric and a polysilicon gate electrode over the channel. Typically, electrical connection or contact is made to the transistor at the source, the drain, and the gate electrode. The contacts provide electrical connection between the transistor and multiple layers of metal lines and vias (which interconnect adjacent layers of metal lines) that interconnect the transistors with other transistors and electrical components.

In some examples, contacting the transistors includes the formation of a silicide in the silicon at the source, drain, and gate. The silicide provides a low resistance and high reliability connection between the conductive contact and the transistor. Frequently, silicide formation involves many processing steps and tools, the steps including a pre-clean, metal sputter, post-sputter clean, silicide anneal, etch, post-etch clean, and others. The numerous steps and tools involved in current silicide formation necessitate expensive, time consuming, and complicated processing.

### BRIEF DESCRIPTION OF THE DRAWINGS

The invention is illustrated by way of example and not by way of limitation in the figures of the accompanying drawings, in which the like references indicate similar elements and in which:

FIG. 1 is a cross-sectional illustration of a partially formed transistor.

FIG. 2 illustrates the structure of FIG. 1 with a patterned contact dielectric layer including three openings formed over the structure.

FIG. 3 illustrates an enlarged view of the structure of FIG. 2 at one of the openings.

FIG. 4 illustrates the structure of FIG. 3 with a siliciding material doped region formed in the substrate and a silicide material layer formed over the patterned contact dielectric layer.

FIG. 5 illustrates the structure of FIG. 4 with a barrier layer formed over the siliciding material doped region and siliciding material layer.

FIG. 6 illustrates the structure of FIG. 5 with a second barrier layer formed over the barrier layer.

FIG. 7 illustrates the structure of FIG. 6 with a conductive fill layer formed over the second barrier layer and filling the opening.

FIG. 8 illustrates the structure of FIG. 7 with portions of the conductive fill layer, the second barrier layer, and the barrier layer removed to expose the patterned contact dielectric layer.

FIG. 9 illustrates the structure of FIG. 8 with the doped region annealed to form a silicide region.

FIG. 10 illustrates a view similar to that of FIG. 1 after the structural changes of FIGS. 2-9.

### DETAILED DESCRIPTION

In various embodiments, apparatuses and methods relating to through contact layer silicide and barrier layer formation are described. However, various embodiments may be practiced without one or more of the specific details, or with other methods, materials, or components. In other instances, well-known structures, materials, or operations are not shown or described in detail to avoid obscuring aspects of various embodiments of the invention. Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale.

In microelectronic integrated circuit fabrication, electrical contact is made at the source, the drain and the gate electrode of the fabricated transistors. Often, the source, the drain, and the gate electrode are silicon (typically a doped crystalline silicon for the source and drain and polycrystalline silicon for the gate electrode). In order to lower the resistance of the contacts and to improve their reliability, a silicide is frequently formed by annealing the silicon of the source, the drain, and the gate electrode with a siliciding material. It is desirable that the manufacturing of the silicide is simple, having as few steps as practicable, and efficient, using fewer manufacturing tools and providing high throughput. Briefly, the present description provides structures and methods that enable the formation of a desirable silicide for transistor contacts that use fewer, simpler manufacturing steps and provide higher throughput. Further, the presently described methods and structures provide silicide only where contact is made with the transistor component, as opposed to previous bulk silicide formation methods. By forming silicide only where it is needed, the present methods and structures offer simplicity in the design and manufacture of the transistor.

The presently described silicide is formed after the formation of a patterned contact layer interlayer dielectric (ILD) over a partially formed transistor. After laying down the patterned ILD, a siliciding material is deposited over the ILD and within the contact openings at deposition parameters that form a doped region of the siliciding material in the substrate (below the substrate surface) within the opening. Then, a barrier layer or layers and a conductive contact fill are formed within the openings and the doped region is annealed to form a silicide region. The silicide formed in such a manner provides few processing steps and a localized silicide that is formed only at the point of contact between the transistor and the conductive contact.

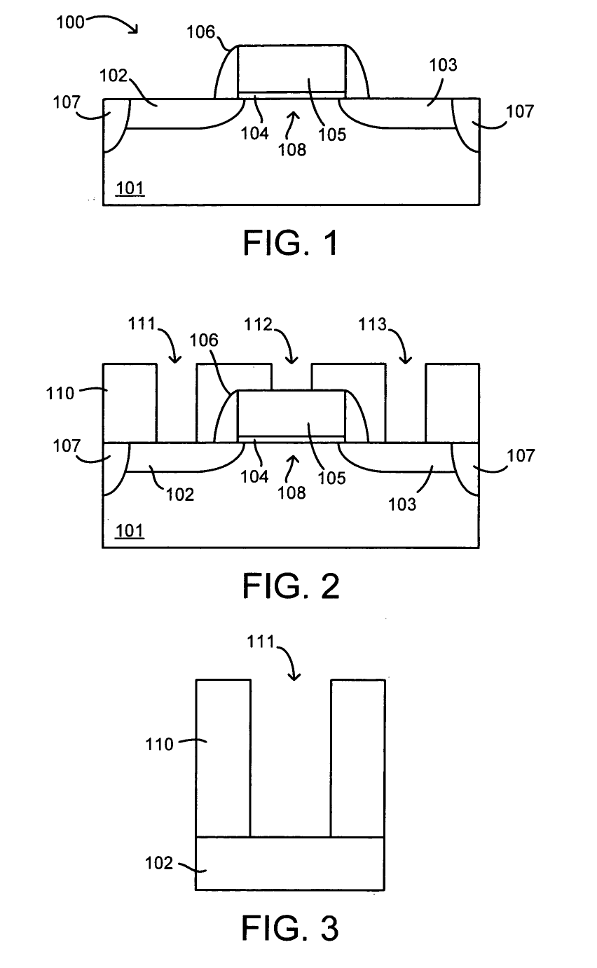

FIGS. 1-10 illustrate methods and structures for providing a highly manufacturable, localized silicide for electrical contact to a transistor.

FIG. 1 illustrates a cross sectional view of a transistor 100 formed in and on a substrate 101. Transistor 100 includes a source region 102 and a drain region 103 separated by a channel region 108. Transistor 100 also includes a gate structure including gate dielectric 104 and gate electrode 105, and sidewall spacers 106. Transistor 100 is electrically isolated from adjacent transistors and/or other electrical components by isolation regions 107. Transistor 100 is formed using standard fabrication techniques known in the art.

Substrate 101 is any suitable substrate, for example those that include silicon, such as a monocrystalline silicon wafer or a silicon on insulator (SOI) wafer. In the illustrated example, source region 102 and drain region 103 are doped silicon regions, where the chosen dopant species and concentration depends on the type of transistor and a variety of design considerations. Further, in the example shown, gate electrode 105 includes a doped polycrystalline silicon. In the formation of electrical contacts with the example transistor shown in FIG. 1, it is therefore desirable to form silicide regions in the source region 102, the drain region 103, and the gate electrode 105.

However, in other examples, a silicide may only be required or desirable in one or more of source region 102, drain region 103, and gate electrode 105. In one example, gate electrode 105 includes a metal gate material to the exclusion of any silicon material such that no silicide is formed in the gate electrode. Further, a planar transistor is shown in FIG. 1 and throughout the present description. In other examples, contact is made using the described methods to non-planar transistors, such as dual-gate transistors and tri-gate transistors.

As shown in FIG. 2, a patterned contact layer 110 including contact openings 111, 112, 113 is formed over the transistor. Patterned contact layer 110 includes any suitable dielectric material and may be characterized as a dielectric layer, interlayer dielectric (ILD), or contact layer dielectric. Patterned contact layer 110 is formed by any suitable patterning technique, such as standard deposition, photolithography, and etch processing steps. Contact openings 111, 112, 113 are aligned with source region 102, gate electrode 105, and drain region 103, respectively.

After forming patterned contact layer 110, an optional clean or etch may be performed to better expose the silicon of source region 102, drain region 103, and gate electrode 105 for subsequent processing.

FIG. 3 illustrates an enlarged view of a cross section at opening 111 and source region 102 of the substrate. In FIGS. 3-9, such an enlarged view is used for the sake of clarity of illustration; the described structures are also formed with respect to opening 112 and gate electrode 105 and opening 113 and drain region 103, but are not shown.

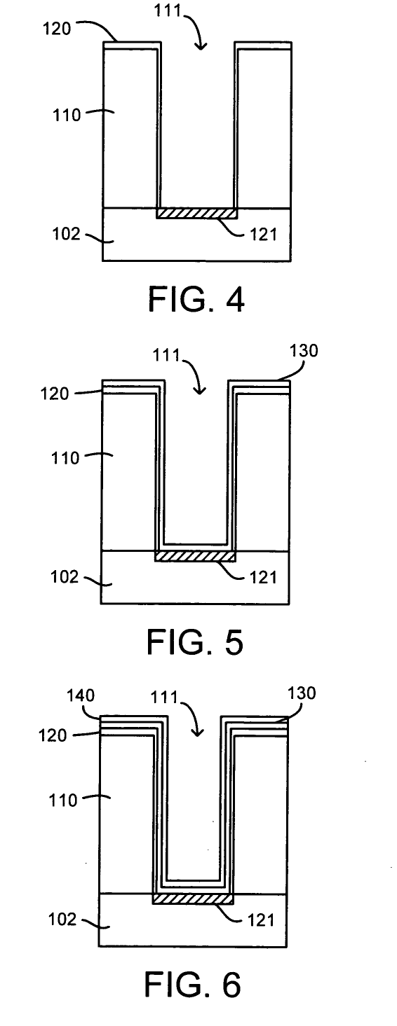

The method continues, as illustrated in FIG. 4, with a siliciding material deposited over patterned contact layer 110 and within opening 111, forming siliciding material layer 120 and doped region 121. The siliciding material is any suitable material that may subsequently form a silicide with silicon (in the structure of FIG. 4, the siliciding material and the silicon in doped region 121 have not yet formed a silicide). In various examples, the siliciding material includes tantalum, titanium, nickel, cobalt, or molybdenum. The siliciding material is deposited such that a doped region 121 is formed within the substrate the doped region having atoms of the siliciding material included within the substrate material and being below the top surface of the substrate in an area that is substantially within opening 111. Therefore, the doped region is formed in the exposed region of the substrate. In one example, some siliciding material may also be formed on the top surface of the substrate within the opening.

Siliciding material layer 120 and doped region 121 are formed by depositing the siliciding material using a physical vapor deposition (PVD) chamber that can apply a voltage bias at the substrate. At high or very high bias conditions (where high bias refers to those biases that are higher than the bias conditions discussed with respect to FIG. 6 for depositing a barrier layer of the same material) the siliciding material forms a doped region 121 in the silicon substrate. The substrate or wafer level voltage and corresponding PVD applied power required to form doped region 121 will vary depending on the siliciding material, the characteristics of the substrate, and the characteristics of the PVD tool. In various examples, the applied power is greater than about 600 Watts, and in some examples the applied power is in the range of about 600 to 1500 Watts. As shown, the siliciding material does not form doped regions in (or only has nominal penetration into) patterned contact layer 110.

Next, as shown in FIG. 5, a nitride barrier layer 130 may optionally be deposited over the siliciding material and within opening 111. In one example, nitride barrier layer 130 includes a nitride of the siliciding material used for doped region 121. In other examples, nitride barrier layer 130 includes the nitride of any suitable material, such as tantalum, titanium, nickel, cobalt, molybdenum, or platinum, the nitride of which will provide a good coverage over the surface at the bottom of opening 111. That coverage blocks extrusion of the subsequent conductive fill into the substrate and prevents array leakage, either of which can cause substantial yield loss.

Nitride barrier layer 130 is formed by any suitable deposition technique. In one example, nitride barrier layer 130 is formed by PVD at low bias conditions in the same tool (either in the same processing chamber or in a separate processing chamber within the same tool) as the siliciding material deposition. By using the same tool for the deposition, the manufacturing process may be simplified by reduction of the required processing equipment and manufacturing throughput time may be decreased by eliminating time-intensive material loading, unloading, and transfer times. As discussed above, the substrate level voltage and applied power depends on the substrate, the chosen deposition material, and manufacturing tool. In various examples, the applied power for the PVD of nitride barrier layer 130 is less than about 600 Watts, and in some examples it is between about 100 and 200 Watts.

The method continues, either with the structure of FIG. 4 or FIG. 5 (the structure of FIG. 5 is shown), with the deposition of a barrier layer 140, as is illustrated in FIG. 6. Barrier layer 140 is any material that provides sufficient coverage of the bottom of opening 111 and a suitable surface for formation of the subsequent fill material. Suitable bottom coverage will limit or eliminate conductive fill material extrusion into the substrate and prevent leakage (similar to the optional nitride barrier layer), as well as providing a suitable surface for the formation of a subsequent conductive fill material, which may agglomerate on the optional nitrided layer.

In one example, the material of barrier layer 140 is the same material as is used as a siliciding material above. In other examples, another material, such as tantalum, titanium, nickel, cobalt, or molybdenum is used. In an example, barrier layer 140 is deposited using a PVD technique at relatively low bias conditions as compared to those used to provide doped region 121. As above, the substrate level voltage and applied power are dependent on a variety of variables (deposition material, substrate, and manufacturing tool). In various examples, the applied power is below about 600 Watts and in some examples, between about 100 and 200 Watts. In particular, in examples where the material of barrier layer 140 and the siliciding material used to form doped region 121 are the same, the applied power for forming the doped region is about 2 to 7 times greater than the applied power for forming the barrier layer.

In one example, barrier layer 140 is formed in the same tool or tool chamber as the deposition of the siliciding material used to form doped region 121. In another example, nitride barrier layer 130 is also formed in the same tool or chamber. As discussed, such processing can reduce the required equipment and processing time of fabrication. Further, since the layers can all be formed in the same tool (and the silicide anneal can be accomplished using a processing anneal required for other processing purposes, as is discussed further below), the silicide described herein can be considered a “one step” silicide process. Such one step processing can replace several silicide steps and effectively eliminate the requirement for a “silicide loop” or series of sequential steps for the formation of a silicide.

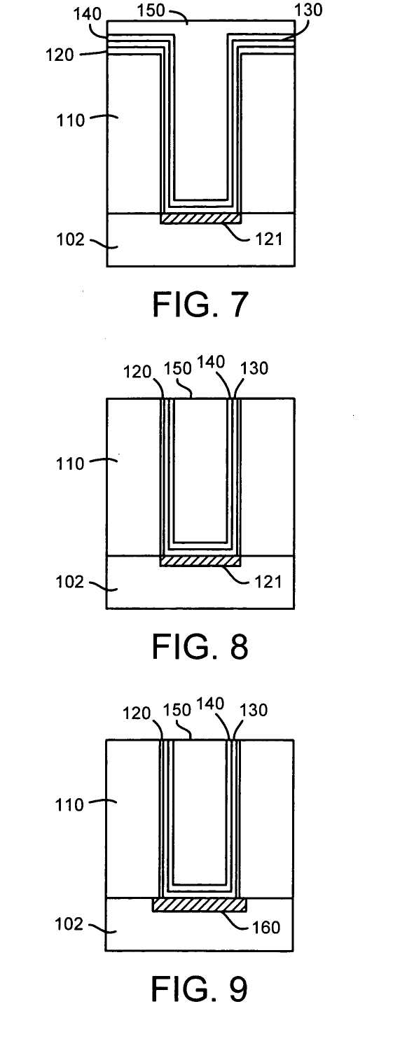

Next, as shown in FIG. 7, a conductive fill 150 is formed within the opening and over barrier layer 140. Conductive fill 150 includes any suitable conductive material, such as copper. In one example, conductive fill 150 includes a stack of layers, including seed layers and a bulk fill layer. Conductive fill 150 is formed by any suitable technique or techniques, including sputter and electroplating steps.

Then, as shown in FIG. 8, portions of conductive fill 150, barrier layer 140, nitride barrier layer 130, and siliciding material layer 120 are removed. The removal may be performed using any suitable technique, such as a planar process including chemical mechanical polishing.

As illustrated in FIG. 9, doped region 121 is annealed or cured to form silicide region 160. The silicide cure temperature and duration depend on the siliciding material species and the desired lateral spread of silicide region 160. In one example, the silicide cure may be accomplished during the post dielectric cure of a dielectric layer formed over patterned contact layer 110 or other processing step, such that an independent anneal or cure step for silicide formation region is not required.

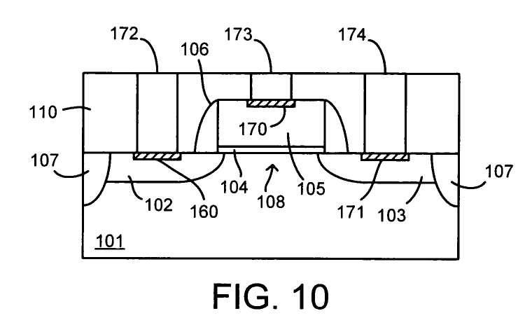

FIG. 10 illustrates an expanded view of the structure of FIG. 9 similar to FIGS. 1 and 2. In FIG. 10, siliciding material layer 120, nitride barrier layer 130, barrier layer 140, and conductive fill 150 are shown as a single contact 172 for the sake of clarity. FIG. 10 also shows contacts 173 and 174 and silicide regions 170, 171, which were formed similarly to contact 172 and silicide region 160.

As shown in FIG. 10, silicide regions 160, 170, 171 are substantially aligned with contacts 172, 173, 174, with a portion of the silicide regions extending laterally beyond the edges of the contacts. Source region 102, drain region 103, and gate electrode 105 have top surfaces that are partially silicide regions and partially bulk material. For example, the top surface of source region 102 includes a first area that is silicide region 160 and a second area that is a bulk source region material. Similarly, the top surface of gate electrode 105 has a first area that is silicide region 170 and a second area that is a bulk gate electrode material, and the top surface of drain region 103 has a first area that is silicide region 171 and a second area that is bulk drain region material. In one example, the top surface areas having the bulk materials are in contact only with patterned contact layer 110. In other examples, contacts 172, 173, 174 may overhang slightly onto the bulk material areas.

The structure of FIG. 10 is then further processed to form a plurality of interconnecting metal line layers and metal via layers that interconnect transistors and electrical components to form an IC. The metal line and via layers also form interconnection to package connection which will connect the IC to the larger electrical system of which it is a part.

It is to be understood that the above description is intended to be illustrative, and not restrictive. Many other embodiments will be apparent to those of ordinary skill in the art upon reviewing the above description. The scope of the invention should, therefore, be determined with reference to the appended claims, along with the full scope of equivalents to which such claims are entitled.

What is claimed is:

1. A method of forming a silicide region for a transistor contact comprising:
forming a dielectric layer having an opening over a substrate including silicon;
depositing a siliciding material over the dielectric layer and the substrate within the opening such that a doped region is formed in the substrate within the opening, wherein the doped region has atoms of the siliciding material included in the substrate; and
annealing the doped region to form the silicide region.

2. The method of claim 1, further comprising:
depositing a barrier layer over the siliciding material.

3. The method of claim 2, wherein depositing the siliciding material comprises physical vapor deposition at a high voltage bias relative to depositing the barrier layer by physical vapor deposition at a low voltage bias.

4. The method of claim 3, wherein the high voltage bias is characterized by an applied power above about 600 Watts.

5. The method of claim 3, wherein the high voltage bias of the siliciding material physical vapor deposition is greater than the low voltage bias of the barrier layer physical vapor deposition by about 2 to 7 times.

6. The method of claim 3, wherein depositing the siliciding material and depositing the barrier layer are performed in the same processing tool.

7. The method of claim 2, wherein the siliciding material and the barrier layer comprise the same material.

8. The method of claim 2, further comprising:
depositing a second barrier layer over the siliciding material after depositing the siliciding material and before depositing the barrier layer, wherein the second barrier layer comprises a nitride layer including the same material as the siliciding material.

9. The method of claim 2, further comprising:
forming a metallic fill over the barrier layer that fills the opening.

10. The method of claim 9, wherein the metallic fill comprises copper.

11. The method of claim 9, further comprising:
removing at least a portion of the siliciding material, the barrier layer, and the metallic fill over the dielectric layer by a planarization process.

12. The method of claim 1, wherein the siliciding material comprises at least one of tantalum, titanium, nickel, cobalt, or molybdenum.

13. A method comprising:
forming a dielectric layer having an opening over a substrate including silicon;
depositing by physical vapor deposition at a first bias voltage a siliciding material over the dielectric layer and the substrate within the opening such that a doped region is formed in the substrate within the opening, wherein the doped region has atoms of the siliciding material included in the substrate;
depositing by physical vapor deposition at a second bias voltage a barrier layer over the siliciding material, wherein the first bias voltage is greater than the second bias voltage; and
annealing the doped region to form a silicide region in the substrate.

14. The method of claim 13, wherein the first bias voltage is about 2 to 7 times the second bias voltage.

15. The method of claim 13, wherein the siliciding material and the barrier layer comprise the same material.

16. The method of claim 13, wherein the siliciding material comprises at least one of tantalum, titanium, nickel, cobalt, or molybdenum.

17. A method comprising:
forming a dielectric layer having an opening over a transistor, the transistor including a source region and a drain region separated by a channel region, and a gate structure including a gate dielectric and a gate electrode over the channel region, wherein the opening is over a portion of the source region;
depositing by physical vapor deposition at a first bias voltage a siliciding material over the dielectric layer and the source region within the opening such that a doped region is formed in the source region within the opening, wherein the doped region has atoms of the siliciding material included in the substrate;
depositing by physical vapor deposition at a second bias voltage a barrier layer over the siliciding material, wherein the first bias voltage is greater than the second bias voltage; and
annealing the doped region to form a silicide in a first area of the source region, wherein the source region includes a second area that does not include the silicide.

18. The method of claim 17, wherein the siliciding material comprises at least one of tantalum, titanium, nickel, cobalt, or molybdenum.

19. The method of claim 17, further comprising:
forming a copper contact within the opening.

20. The method of claim 17, wherein the first voltage bias is greater than the second voltage bias by about 2 to 7 times.

21. A transistor comprising:
a source region and a drain region in a substrate, wherein the source region and the drain region are separated by a channel region;
a gate structure including a gate dielectric and a gate electrode over the channel region;
a silicide region formed within a first area of a surface of the source region, wherein the surface of the source region includes a second area that includes a bulk doped source region material that is in contact with a contact layer dielectric material, and wherein the silicide region comprises at least one of tantalum, titanium, nickel, cobalt, or molybdenum.

22. The transistor of claim 21, further comprising:
a copper contact in an opening in the contact layer dielectric material and in contact with the silicide region.

23. The transistor of claim 22, wherein the copper contact is not in contact with the bulk doped source region material.
